(19) United States
(12) Patent Application Publication
(10) Pub. No.: US 2024/0266328 A1
(43) Pub. Date: Aug. 8, 2024

(54) LIGHT-EMITTING MODULE AND DISPLAY DIVICE

(71) Applicant: HUBEI SAN'AN OPTOELECTRONICS CO., LTD., Ezhou (CN)

(72) Inventors: Zhiyang ZENG, Quanzhou (CN); Zhen-duan LIN, Xiamen (CN); Weihong CHEN, Quanzhou (CN); Junpeng SHI, Xiamen (CN); Jieling WANG, Quanzhou (CN); Yaxin QIU, Quanzhou (CN); Qinghe CHEN, Quanzhou (CN); Chongde HONG, Quanzhou (CN)

(21) Appl. No.: 18/436,046

(22) Filed: Feb. 8, 2024

Related U.S. Application Data
(63) Continuation of application No. PCT/CN2021/143223, filed on Dec. 30, 2021.

(51) Int. Cl. H01L 25/075; H01L 33/62

(52) U.S. Cl. CPC H01L 25/0753; H01L 33/62; H01L 2933/0066

(57) ABSTRACT

A light-emitting module and a display device are provided, the light-emitting module includes light-emitting elements, a filling layer, a wiring layer and conductive solder pads, the light-emitting elements are arranged at intervals, and a thickness of each light-emitting element is smaller than or equal to 15 μm; the filling layer is filled between adjacent light-emitting elements; the wiring layer is disposed on the light-emitting elements, and is configured to electrically connect to the light-emitting elements; the conductive solder pads are disposed on a side of the wiring layer facing away from the light-emitting elements, and are electrically connected to the wiring layer; specifically, the filling layer contains a black filling component, a particle size of the black filling component is smaller than or equal to 1/10 of the thickness of the light-emitting element, or the particle size of the black filling component is smaller than or equal to 1 μm.

### TECHNICAL FIELD

The disclosure relates to the field of semiconductor technologies, and more particularly to a light-emitting module and a display device.

### BACKGROUND

Light-emitting diodes are widely used in display devices, lamps for vehicles, general lighting lamps and other fields due to their high reliability, long service life and low power consumption. For example, the light-emitting diodes can be used as backlight sources for various display devices. In order to provide effective mechanical protection for the light-emitting diodes, the light-emitting diodes are commonly encapsulated to form a light-emitting module, which can strengthen heat dissipation, improve light-emitting efficiency, and optimize beam distribution. However, reliability of the light-emitting module obtained by an existing method is poor, how to obtain a light-emitting module with high-reliability is still a difficult problem.

### SUMMARY

According to an embodiment of the disclosure, a light-emitting module includes: multiple light-emitting elements, a filling layer, a wiring layer, and conductive solder pads. The multiple light-emitting elements are arranged at intervals, and a thickness of each of the multiple light-emitting elements is smaller than or equal to 15 microns (μm). The filling layer is filled between adjacent two of the multiple light-emitting elements. The wiring layer is disposed on the multiple light-emitting elements, and is used to electrically connect to the multiple light-emitting elements. The conductive solder pads are disposed on a side of the wiring layer facing away from the multiple light-emitting elements, and are electrically connected to the wiring layer. The filling layer fills a black filling component, and a particle size of the black filling component is smaller than or equal to 1/10 of the thickness of each of the multiple light-emitting elements.

According to another embodiment of the disclosure, a light-emitting module includes: multiple light-emitting elements, a wiring layer and conductive solder pads. The multiple light-emitting elements are arranged at intervals. The wiring layer is disposed on the multiple light-emitting elements, and is used to electrically connect to the multiple light-emitting elements. The conductive solder pads are disposed on a side of the wiring layer facing away from the multiple light-emitting elements, and are electrically connected to the wiring layer; and a thickness of each of the conductive solder pads is larger than 5 μm, and the wiring layer is in direct contact with the conductive solder pads.

According to another embodiment of the disclosure, a light-emitting module includes: multiple light-emitting elements, a wiring layer and conductive solder pads. The multiple light-emitting elements are arranged at intervals. The wiring layer is disposed on the multiple light-emitting elements, and is used to electrically connect to the multiple light-emitting elements. The conductive solder pads are disposed on a side of the wiring layer facing away from the multiple light-emitting elements, and are electrically connected to the wiring layer. The wiring layer defines a first area and a second area, the first area is an area that the wiring layer overlaps with the conductive solder pads in a vertical direction, and the second area is an area connecting the first area and the multiple light-emitting elements. A connection position is defined between the first area and the second area, and a length of the connection position between the first area and the second area is larger than 20 μm, or a length of the connection position between the first area and the second area is over 40% of a length of each side of each of the conductive solder pads.

According to another embodiment of the disclosure, a light-emitting module includes: multiple light-emitting elements, a filling layer, a wiring layer, conductive solder pads and an adhesion layer. The multiple light-emitting elements are arranged at intervals. The filling layer is filled between adjacent two of the multiple light-emitting elements. The wiring layer is disposed on the multiple light-emitting elements, and is used to electrically connect to the multiple light-emitting elements. The conductive solder pads are disposed on a side of the wiring layer facing away from the multiple light-emitting elements, and are electrically connected to the wiring layer. The adhesion layer is disposed between the multiple light-emitting elements and the filling layer.

According to another embodiment of the disclosure, a light-emitting module includes: multiple light-emitting elements, a wiring layer, conductive solder pads, an encapsulation layer and a protective solder pad. The multiple light-emitting elements are arranged at intervals. The wiring layer is disposed on the multiple light-emitting elements, and is used to electrically connect to the multiple light-emitting elements. The conductive solder pads are disposed on a side of the wiring layer facing away from the multiple light-emitting elements, and are electrically connected to the wiring layer. The encapsulation layer is disposed around the conductive solder pads. The protective solder pad is disposed on a side of the encapsulation layer facing away from the multiple light-emitting elements, and is located on a thimble operation area of the light-emitting module.

According to another embodiment of the disclosure, a light-emitting module includes: multiple light-emitting elements, a wiring layer, conductive solder pads and a conductive protective layer. The multiple light-emitting elements are arranged at intervals. The wiring layer is disposed on the multiple light-emitting elements, and is used to electrically connect to the multiple light-emitting elements. The conductive solder pads are disposed on a side of the wiring layer facing away from the multiple light-emitting elements, and are electrically connected to the wiring layer. The conductive protective layer is disposed between the conductive solder pads and the wiring layer.

According to another embodiment of the disclosure, a preparation method of a light-emitting module includes: providing a first transparent layer; arranging multiple light-emitting elements on a surface of the first transparent layer at fixed intervals; preparing a filling layer around the multiple light-emitting elements; preparing a wiring layer on the filling layer; preparing conductive solder pads on the wiring layer, where a thickness of each of the conductive solder pads is larger than 5 μm, and the conductive solder pads are in direct contact with the wiring layer; and preparing an encapsulation layer around the conductive solder pads.

### BRIEF DESCRIPTION OF DRAWINGS

In order to provide a clearer explanation of technical solutions in embodiments of the disclosure, drawings required in the embodiments will be simply introduced below. It should be understood that the following drawings merely show some of the embodiments of the disclosure, therefore, the drawings should not be considered as limiting a scope. For those skilled in the art, other relative drawings can be obtained without creative work according to the drawings.

FIG. 1 illustrates a schematic plane diagram of a light-emitting module according to an embodiment 1 of the disclosure.

FIG. 2 illustrates a schematic section diagram of the light-emitting module taken along a section line A-A′ in FIG. 1 according to the embodiment 1 of the disclosure.

FIG. 3 illustrates a schematic section diagram of a light-emitting module according to an embodiment 2 of the disclosure.

FIG. 4 illustrates a schematic section diagram of the light-emitting module according to the embodiment 2 of the disclosure.

FIG. 5 illustrates a schematic section diagram of a light-emitting module according to an embodiment 3 of the disclosure.

FIG. 6 illustrates a flowchart of a preparation method of a light-emitting module according to an embodiment 4 of the disclosure.

FIGS. 7a-15 illustrate schematic section diagrams of preparation processes of the light-emitting module and schematic plane diagrams corresponding to partial preparation processes according to the embodiment 4 of the disclosure.

FIG. 16 illustrates a schematic plane diagram of a light-emitting module according to an embodiment 5 of the disclosure.

FIG. 17 illustrates a schematic plane diagram of the light-emitting module in FIG. 16 omitting conductive solder pads for easy labeling of a wiring layer.

FIG. 18 illustrates a schematic section diagram of a light-emitting module according to an embodiment 6 of the disclosure.

FIG. 19 illustrates a schematic section diagram of the light-emitting module according to the embodiment 6 of the disclosure.

FIG. 20 illustrates a schematic plane diagram of a light-emitting module according to an embodiment 7 of the disclosure.

FIG. 21 illustrates a schematic plane diagram of the light-emitting module according to the embodiment 7 of the disclosure.

### LIST OF REFERENCE NUMBERS

100—transparent layer; 1001—first transparent layer; 1002—second transparent layer; 200—light-emitting element; 201—first light-emitting element; 202—second light-emitting element; 203—third light-emitting layer; 210—filling layer; 220—adhesion layer; 300—wiring layer; 3000—total wiring layer; 3001—first area; 3002—second area; 3003—third area; 3004—connection position between the first area and the second area; 301—first sub wiring; 302—second sub wiring; 303—third sub wiring; 304—fourth sub wiring; 305—pin; 310—first layer; 320—second layer; 330—insulation layer; 400—conductive protective layer; 500—conductive solder pad; 501 first solder pad; 502—second solder pad; 503—third solder pad; 504—fourth solder pad; 510—conductive layer; 520—bonding layer; 530—protective layer; 540—eutectic layer; 600—encapsulation layer; 700—seed layer; 800—protective solder pad.

### DETAILED DESCRIPTION OF EMBODIMENTS

Implementation methods of the disclosure are described through specific embodiments below, and those skilled in the art can easily understand other advantages and benefits of the disclosure from a content disclosed in the specification. The disclosure can also be implemented or operated through different specific implementation methods, and details in the disclosure can be modified or changed based on different perspectives and applications without deviating from a spirit of the disclosure.

In descriptions of the disclosure, it should be noted that an orientation or position relationship indicated by terms “up” and “down” is based on an orientation or position relationship shown in the drawings, or an orientation or position relationship habitually placed during use of a product of the disclosure, which is merely for convenience of describing the disclosure and simplifying description, and not to indicate or imply that a device or a component referred to must have a specific orientation, and be constructed and operated in the specific orientation, therefore, it cannot be understood as a limitation on the disclosure. In addition, terms “first” and “second” are merely used to distinguish descriptions and cannot be understood as indicating or implying relative importance.

### Embodiment 1

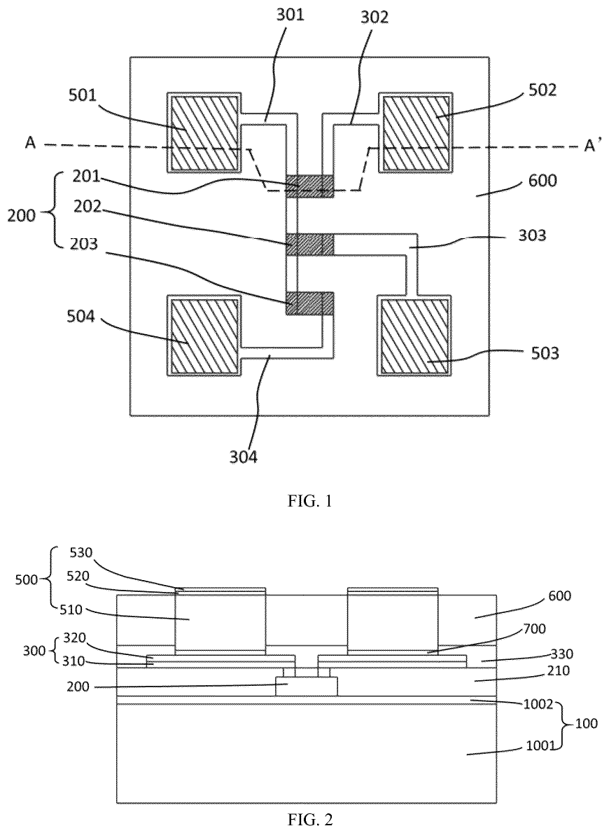

FIG. 1 illustrates a schematic plane diagram for describing a light-emitting module of the embodiment 1 of the disclosure, and FIG. 2 illustrates a schematic section diagram of the light-emitting module taken along a section line A-A′ in FIG. 1.

As shown in FIG. 1 and FIG. 2, the light-emitting module includes multiple light-emitting elements 200, a filling layer 210, a wiring layer 300 and conductive solder pads 500. The multiple light-emitting elements with different wavelength ranges are arranged at intervals. The filling layer 210 is filled in a gap between every adjacent two light-emitting elements 200, to thereby electrically isolate the adjacent light-emitting elements 200. The wiring layer 300 is disposed on the multiple light-emitting elements 200, and is used to electrically connect to the light-emitting elements 200. The conductive solder pads 500 are disposed on a side of the wiring layer 300 facing away from the light-emitting elements 200, and are electrically connected to the light-emitting elements 200 through the wiring layer 300.

In an embodiment, the light-emitting element 200 mainly refers to a micron scale light-emitting diode, a range of each of a width and a length of each light-emitting element 200 is 2-5 microns (μm), 5-10 μm, 10-20 μm, 20-50 μm, or 50-100 μm, and a thickness range of the light-emitting element 200 is 2-15 μm, specifically, the thickness range is 5-10 μm. In the embodiment, the light-emitting module includes a first light-emitting element 201, a second light-emitting element 202 and a third light-emitting element 203.

In an embodiment, each light-emitting element 200 includes a semiconductor stacking layer, the semiconductor stacking layer can include a first semiconductor layer, a second semiconductor layer and an active layer disposed between the first semiconductor layer and the second semiconductor layer, and the first semiconductor layer, the second semiconductor layer and the active layer are arranged in sequence. The first semiconductor layer is a N-type semiconductor layer, the second semiconductor layer is a P-type semiconductor, the active layer is a multilayer quantum well layer, and the active layer can provide emission of red, green, or blue light. The N-type semiconductor layer, the multilayer quantum well layer, and the P-type semiconductor layer are merely basic constituent units of the light-emitting element 200, on this basis, the light-emitting element 200 can include other functional structural layers with optimization effects on a performance of the light-emitting element 200.

The first light-emitting element 201, the second light-emitting element 202, and the third light-emitting element 203 respectively emit light in different wavelength ranges. For example, the first light-emitting element 201 emits blue light, the second light-emitting element 202 emits green light, and the third light-emitting element 203 emits red light. In an embodiment, different light-emitting elements 200 can have different semiconductor stacking layers, thus directly emitting light with different wavelength ranges. A specific material of the semiconductor stacking layer can be selected according to a wavelength of the emitted light, and the specific material includes but not limit to at least one selected from the group consisting of aluminium gallium arsenide (AlGaAs), gallium arsenide phosphate (GaAsP), aluminium gallium indium phosphide (AlGaInP), gallium nitride (GaN), indium gallium nitride (InGaN), zinc selenide (ZnSe), and gallium phosphide (GaP). In another embodiment, different light-emitting elements 200 can have a same semiconductor stacking layer, for example, the semiconductor stacking layers in the first light-emitting element 201, the second light-emitting element 202 and the third light-emitting element 203 all emit blue light, a wavelength conversion layer is disposed on a light-emitting surface of the second light-emitting element 202 to convert the emitted blue light to green light, and a wavelength conversion layer is disposed on a light-emitting surface of the third light-emitting element 203 to convert the emitted blue light to red light.

Each light-emitting element 200 further includes a first electrode and a second electrode. The semiconductor stacking layer is provided with a mesa exposing the first semiconductor layer, the first electrode is disposed on the mesa and is electrically connected to the first semiconductor layer, and the second electrode is disposed on the second semiconductor layer and is electrically connected to the second semiconductor layer.

In an embodiment, a thickness difference between the light-emitting elements 200 is smaller than or equal to 5 μm, which can effectively improve a transfer qualification rate of the light-emitting module transferring to a transparent layer 100 described later, so as to improve a light-emitting effect of the light-emitting module.

In an embodiment, as shown in FIG. 1 and FIG. 2, the light-emitting module further includes the transparent layer 100, and the light-emitting elements 200 are disposed on the transparent layer 100. A surface of the transparent layer 100 facing away from the light-emitting elements 200 is a light-emitting surface of the light-emitting module, that is, light emitted from the light-emitting elements 200 is emitted to outside through the transparent layer 100. The transparent layer 100 has a transmittance of over 60% in a visible light range.

In an embodiment, as shown in FIG. 2, the transparent layer 100 includes a first transparent layer 1001 and a second transparent layer 1002, and the second transparent layer 1002 is disposed between the first transparent layer 1001 and the light-emitting elements 200.

A material of the first transparent layer 1001 can be selected from inorganic transparent materials such as glass, transparent ceramic and sapphire. In an embodiment, the light-emitting module needs to have a certain thickness for client use, thus, a thickness of the first transparent layer 1001 is larger than 10 μm, specifically, the thickness of the first transparent layer 1001 is in a range of 30-50 μm, 50-100 μm or 100-300 μm.

The second transparent layer 1002 is disposed between the first transparent layer 1001 and the light-emitting elements 200, to make the light-emitting elements 200 be bonded on the first transparent layer 1001 through the second transparent layer 1002. The second transparent layer 1002 can completely cover a whole surface of the first transparent layer 1001. However, it is not limited to this, the second transparent layer 1002 can be merely disposed below the light-emitting elements 200, to make the light-emitting elements 200 be bonded on the first transparent layer 1001 through the second transparent layer 1002.

Different light-emitting elements 200 usually have different thicknesses, the second transparent layer 1002 is disposed between the first transparent layer 1001 and the light-emitting elements 200, which reduces a height difference between the light-emitting surfaces of the light-emitting elements 200, so that light emitted from sides of the light-emitting elements 200 is absorbed as much as possible by the filling layer 210 described below, so as to improve a contrast of the light-emitting module. A thickness of the second transparent layer 1002 is in a range of 1-15 μm or 3-10 μm. When the thickness of the second transparent layer 1002 is larger than 15 μm, an alignment accuracy of the light-emitting element 200 may be affected.

In an alternative embodiment, since the inorganic transparent materials such as sapphire have high costs and complex preparation processes, the material of the first transparent layer 1001 can be also selected from thermosetting organic materials with low costs, such as epoxy resin, silica gel, and polyimide. In an embodiment, the first transparent layer 1001 can be a member formed by dispersing nanoparticles such as zirconium dioxide, silicon oxide, aluminum oxide and boron nitride into organic transparent materials such as the epoxy resin, the silica gel and the polyimide. Specifically, the nanoparticles such as the zirconium dioxide, the silicon oxide, the aluminum oxide and the boron nitride can improve a strength of the first transparent layer 1001. In addition, the contrast of the light-emitting module can be adjusted through adjusting contents of the nanoparticles such as the zirconium dioxide, the silicon oxide, the aluminum oxide and the boron nitride. In an embodiment, when the material of the first transparent layer 1001 is the thermosetting organic material, the second transparent layer 1002 can be omitted.

In an embodiment, as shown in FIG. 1 and FIG. 2, the light-emitting module further includes the filling layer 210, and the filling layer is filled between the adjacent light-emitting elements 200 or around a side wall of each light-emitting element 200, which can prevent color mixing or light interference between the adjacent light-emitting elements 200, so as to improve the contrast of the light-emitting module. The filling layer 210 is provided as a black bonding layer absorbing light.

The thickness range of the light-emitting element 200 is 2-15 μm, and the interval between the adjacent light-emitting elements 200 is smaller than 50 μm, thus, a material with good fluidity is adopted to solidify when preparing the filling layer 210. A particle size of a black filling component filled in the filling layer 210 is smaller than or equal to 1/10 of the thickness of the light-emitting element 200, which can avoid a problem of poor covering effect of the filling layer 210 on the light-emitting elements 200 caused by excessive particle size of the black filling component, and thereby affect the contrast of the light-emitting module. The filling layer 210 can be specifically a member formed by dispersing the black filling component with the particle size not greater than 1 μm into a transparent or semitransparent material such as the silica gel, the epoxy resin, the polyimide, low temperature glass, polysiloxane, or polysilazane. The black filling component in the filling layer 210 includes, but is not limited to at least one selected from the group consisting of carbon black, titanium nitride, iron oxide, ferrosoferric oxide and iron powder. A particle size range of the black filling component is 10-100 nanometers (nm), 100-100 nm, 200-300 nm or 300-500 nm. The filling layer 210 can adopts a black dye.

The filling layer 210 covers at least 50% of a thickness of a side wall of the light-emitting element 200 proximate to a light-emitting surface of the light-emitting element, specifically, the filling layer 210 covers all of the side wall of the light-emitting element 200, which can prevent the color mixing or the light interference between the adjacent light-emitting elements 200, so as to improve the contrast of the light-emitting module. In an alternative embodiment, a thickness of the filling layer 210 can be larger than the thickness of the light-emitting element 200, which can prevent light interference caused by light leakage at a bottom of the light-emitting element 200. The thickness of the filling layer 210 is smaller than 15 sm.

In an embodiment, as shown in FIG. 1 and FIG. 2, the wiring layer 300 is disposed on the light-emitting elements 200, and is used to electrically connect to the light-emitting elements 200. The wiring layer 300 includes multiple wiring, and an insulation layer 330 is filled around the wiring layer 300, to thereby electrically isolate adjacent wiring.

The wiring layer 300 includes a first sub wiring 301, a second sub wiring 302, a third sub wiring 303 and a fourth sub wiring 304. The first sub wiring 301 is used as a common wiring, first electrodes of the first light-emitting element 201, the second light-emitting element 202 and third light-emitting element 203 are jointly connected to the first sub wiring 301, a second electrode of the first light-emitting element 201 is connected to the second sub wiring 302, a second electrode of the second light-emitting element 202 is connected to the third sub wiring 303, and a second electrode of the third light-emitting element 203 is connected to the fourth sub wiring 304. The first sub wiring 301, the second sub wiring 302, the third sub wiring 302 and the fourth sub wiring 304 of the wiring layer 300 can be jointly disposed on the filling layer 210.

In an alternative embodiment, the first sub wiring 301 is used as a common wiring, second electrodes of the first light-emitting element 201, the second light-emitting element 202 and the third light-emitting element 203 are jointly connected to the first sub wiring 301, a first electrode of the first light-emitting element 201 is connected to the second sub wiring 302, a first electrode of the second light-emitting element 202 is connected to the third sub wiring 303, and a first electrode of the third light-emitting element 203 is connected to the fourth sub wiring 304. The first sub wiring 301, the second sub wiring 302, the third sub wiring 303 and the fourth sub wiring 304 of the wiring layer 300 can be jointly disposed on the filling layer 210.

The wiring layer 300 has opposite upper and lower surfaces, the lower surface of the wiring layer 300 is in contact with the filling layer 210 and the light-emitting elements 200, and the upper surface of the wiring layer 300 is used to prepare the insulation layer 330.

The wiring layer 300 can be a single layer or a multilayer prepared by at least one material selected from the group consisting of titanium, copper, chromium, nickel, gold, platinum, aluminum, titanium nitride, tantalum nitride and tantalum. In the embodiment, the wiring layer 300 can include a first layer 310 and a second layer 320, the first layer 310 is in direct contact with the light-emitting elements 200, and the second layer 320 is disposed on the first layer 310. The first layer 310 is used to bond the second layer 320 on the light-emitting elements 200 and the filling layer 210, and the second layer 320 mainly plays a conductive role. A material of the first layer 310 includes, but is not limited to at least one selected from the group consisting of the titanium, the nickel, the titanium nitride, the tantalum nitride and the tantalum, and a material of the second layer 320 includes, but is not limited to at least one selected from the group consisting of the copper, the aluminum and the gold. The wiring layer 300 can be prepared by means of sputtering, evaporation and the like.

In an embodiment, a thickness of the wiring layer 300 is in a range of 50-1000 nm. Specifically, a thickness of the first layer 310 is in a range of 10-200 nm, a thickness of the second layer 320 is in a range of 200-800 nm, and the thickness of the first layer 310 is smaller than the thickness of the second layer 320.

In an embodiment, as shown in FIG. 1 and FIG. 2, the conductive solder pads 500 are disposed on a side of the wiring layer 300 facing away from the light-emitting elements 200, and are electrically connected to the light-emitting elements 200 through the wiring layer 300.

The conductive solder pads 500 include a first solder pad 501, a second solder pad 502, a third solder pad 503 and a fourth solder pad 504. The first solder pad 501 is used as a common solder pad, the first electrodes of the first light-emitting element 201, the second light-emitting element 202 and the third light-emitting element 203 are jointly connected to the first solder pad 501 through the first sub wiring 301, the second electrode of the first light-emitting element 201 is connected to the second solder pad 502 through the second sub wiring 302, the second electrode of the second light-emitting element 202 is connected to the third solder pad 503 through the third sub wiring 303, and the second electrode of the third light-emitting element 203 is connected to the fourth solder pad 504 through the fourth sub wiring 304.

In an alternative embodiment, the first solder pad 501 is used as a common solder pad, the second electrodes of the first light-emitting element 201, the second light-emitting element 202 and the third light-emitting element 203 are jointly connected to the first solder pad 501 through the first sub wiring 301, the first electrode of the first light-emitting element 201 is connected to the second solder pad 502 through the second sub wiring 302, the first electrode of the second light-emitting element 202 is connected to the third solder pad 503 through the third sub wiring 303, and the first electrode of the third light-emitting element 203 is connected to the fourth solder pad 504 through the fourth sub wiring 304.

In an embodiment, each conductive solder pad 500 includes a conductive layer 510. The conductive layer 510 can be a single layer or a multilayer prepared by at least one material selected from the group consisting of the titanium, the copper, the gold and the platinum, and a thickness of the conductive layer 510 is in a range of 10-50 μm, for example, 20 μm, 30 μm, and 40 μm.

In an alternative embodiment, the conductive solder pad 500 includes a conductive layer 510 and a protective layer 530 disposed on the wiring layer 300 in sequence. Before installing the light-emitting module on a display device, the protective layer 530 completely covers an upper surface of the conductive layer 510, which can effectively prevent oxidation of the conductive layer 510, and improve stability of the light-emitting module. When the light-emitting module is installed on the display device, the protective layer 530 is damaged or removed. The protective layer 530 cannot affect associativity and conductivity of the conductive solder pad 500, and a thickness of the protective layer 530 is in a range of 25-50 nm.

The protective layer 530 can be prepared by a metal material such as the gold or the platinum. During installing the light-emitting module on the display device, the conductive solder pads 500 are welded with a circuit board through a welding material under a preset temperature. During welding, the welding material flows and generates deformation, and the deformation of the welding material may damage integrity of the protective layer 530 prepared by the metal material such as the gold or the platinum.

In an alternative embodiment, the protective layer 530 can be prepared by an organic material such as organic solderability preservative (OSP). during installing the light-emitting module on the display device, the conductive solder pads 500 are weld with the circuit board through the welding material under the preset temperature, and the organic material such as OSP is dissolved under the preset temperature, to thereby be removed.

In an embodiment, a bonding layer 520 is further disposed between the conductive layer 510 and the protective layer 530. The bonding layer 520 can be a single layer or a multilayer prepared by at least one material selected from the group consisting of the chromium, the titanium, the nickel, the tantalum nitride and the tantalum. A thickness of the bonding layer 520 is in a range of 3-5 μm.

In an embodiment, as shown in FIG. 2, an encapsulation layer 600 is filled around the conductive solder pads 500, to thereby electrically isolate adjacent solder pads. The encapsulation layer 600 is provided as a glue layer for absorbing light, specifically, the encapsulation layer 600 is a member formed by dispersing a black filling component into the transparent or semitransparent material such as the silica gel, the epoxy resin, the polyimide, the low-temperature glass, the polysiloxane or the polysilazane. The black filling component in the encapsulation layer 600 includes, but is not limited to at least one selected from the group consisting of the carbon black, the titanium nitride, the iron oxide, the ferrosoferric oxide and the iron powder.

However, the thicknesses of the light-emitting elements 200 and the wiring layer 300 are thin, the encapsulation layer 600 is configured to have a certain thickness to protect the light-emitting elements 200 and the wiring layer 300 from damage from external factors. The thickness of the encapsulation layer 600 is larger than 20 μm, thus, the thickness of the conductive solder pad 500 is also larger than 20 μm. The encapsulation layer 600 is doped with doped particles with a particle size larger than 1 μm, and the doped particles can be silica, which can enhance a mechanical property of the encapsulation layer 600, so as to better protect the light-emitting elements 200 and the wiring layer 300.

In an embodiment, a surface of the encapsulation layer 600 facing away from the wiring layer 300 is flush with a surface of the conductive layer 510 in the conductive solder pad 500 facing away from the wiring layer 300.

In an embodiment, the thickness of the conductive solder pad 500 is larger than or equal to 5 μm, and it can be prepared through an electroplating method.

In an embodiment, as shown in FIG. 2, the insulation layer 330 is disposed on an upper surface of the wiring layer 300, and is filled around the wiring in the wiring layer 300. The insulation layer 330 defines through holes above the upper of the wiring layer 300 for preparing the conductive solder pads 500. A number of the through holes is the same as a number of the conductive solder pads 500, that is, one conductive solder pad 500 corresponds to one through holes.

The insulation layer 330 can be a member formed by a material such as the epoxy resin, the polysiloxane or photoresist, which can avoid oxidation of the wiring layer 300, electrically isolate different wiring, and avoid a leakage failure of the light-emitting module.

The upper surface of the wiring layer 300 is provided with a seed layer 700, the seed layer 700 conducts electricity to prepare the conductive solder pads 500 by the electroplating method. The seed layer 700 can be a single layer or a multiplayer prepared by at least one material selected from the group consisting of the titanium, the copper, the gold, and the platinum. In the embodiment, the seed layer 700 is a titanium/copper stacked layer, and a thickness of the seed layer is in a range of 100-2000 nm.

### Embodiment 2

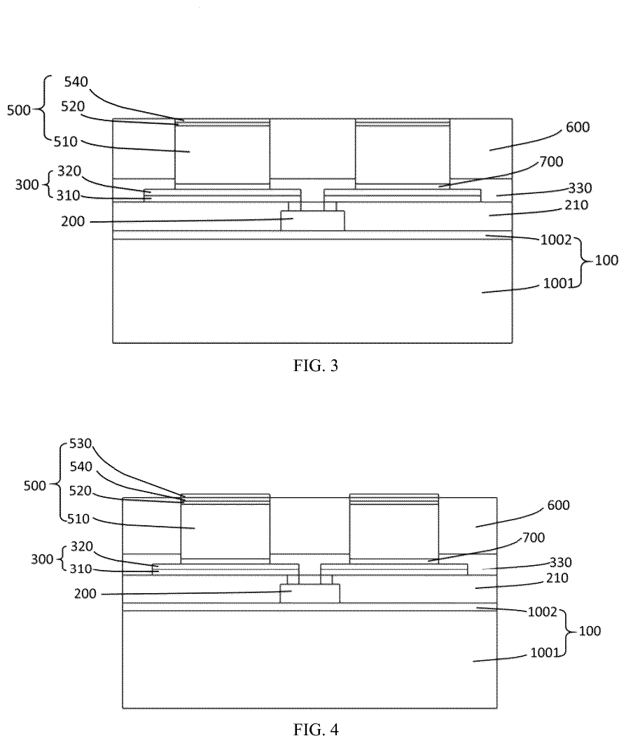

FIG. 3 illustrates a schematical section diagram for describing a light-emitting module according the embodiment 2 of the disclosure. It is different from the embodiment 1 in that, each conductive solder pad 500 includes a conductive layer 510, a bonding layer 520 and a eutectic layer 540 disposed on the wiring layer 300 in sequence.

The conductive layer 510 can be a single layer or a multilayer prepared by at least one material selected from the group consisting of titanium, copper, gold and platinum, and a thickness of the conductive layer 510 is in a range of 10-50 μm, for example, 20 μm, 30 μm, and 40 μm.

The bonding layer 520 is disposed between the conductive layer 510 and the eutectic layer 540, and the bonding layer 520 can be a single layer or a multilayer prepared by at least one material selected from the group consisting of chromium, the titanium, nickel, tantalum nitride and tantalum. A thickness of the bonding layer 520 is in a range of 3-5 μm.

The eutectic layer 540 can be a single layer or a multilayer prepared by at least one material selected from the group consisting of tin (Sn), tin sliver (SnAg) and gold tin (AuSn), and a thickness of the eutectic layer 540 is in a range of 10-50 nm. The eutectic layer 540 can effectively enhance a bonding force of the light-emitting module when applying the light-emitting module to a circuit board, and it is not necessary to print solder paste again or print a small amount of the solder paste when applying, thus improving a convenience for client use.

In an embodiment, a surface of the encapsulation layer 600 facing away from the wiring layer 300 is flush with a surface of the eutectic layer 540 in the conductive solder pad 500 facing away from the wiring layer 300, so that a surface of the light-emitting module becomes flat, which is beneficial to the client use.

In an embodiment, as shown in FIG. 4, the conductive solder pad 500 further includes a protective layer 530 disposed on the eutectic layer 540. Before installing the light-emitting module on the display device, the protective layer 530 completely covers upper surfaces of the eutectic layer 540 and the conductive layer 510, which can effectively prevent oxidation of the eutectic layer 540 and the conductive layer 510, and improve the stability of the light-emitting module. When the light-emitting module is installed on the display device, the protective layer 530 is damaged or removed. The protective layer 530 has no effects on the associativity and the conductivity of the conductive solder pads 500, and a thickness of the protective layer 530 is in a range of 25-50 nm.

The protective layer 530 can be prepared by a metal material such as the gold or the platinum, during installing the light-emitting module on the display device, the conductive solder pads 500 are welded with a circuit board through a welding material under a preset temperature. During welding, the welding material flows and generates deformation, and the deformation of the welding material may damage integrity of the protective layer 530 prepared by the metal material such as the gold or the platinum.

In an alternative embodiment, the protective layer 530 can be prepared by an organic material such as OSP. During installing the light-emitting module on the display device, the conductive solder pads 500 are weld with the circuit board through the welding material under the preset temperature, and the organic material such as OSP is dissolved under the preset temperature, to thereby be removed.

### Embodiment 3

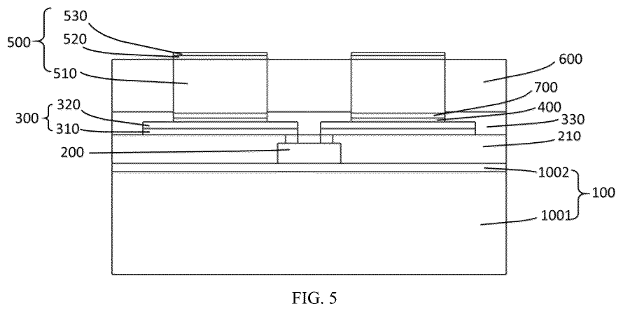

FIG. 5 illustrates a schematic section diagram for describing a light-emitting module according to the embodiment 3 of the disclosure.

It is different from the embodiment 1 or the embodiment 2 in that: a conductive protective layer 400 is disposed on the wiring layer 300, and the conductive protective layer 400 is disposed between the wiring layer 300 and the conductive solder pads 500. Specifically, the conductive protective layer 400 is disposed between the wiring layer 300 and the seed layer 700. Before preparing the seed layer 700 or the conductive solder pads 500, the wiring layer 300 is always exposed, and is easy oxidated by air. Therefore, the conductive protective layer 400 is disposed between the conductive solder pads 500 and the wiring layer 300, the wiring layer 300 is protected in advance by the conductive protective layer 400, so as to prevent a part in the wiring layer 300 for connecting with the seed layer 700 or the conductive solder pads 500 from being oxidized due to exposure to air, and make the conductive solder pads 500 have the good associativity and conductivity.

As shown in FIG. 5, the part in the wiring layer 300 for connecting with the conductive solder pads 500 is provided with the conductive protective layer 400. The conductive protective layer 400 is disposed in the through holes in the insulation layer 330. However, it is not limited to this, in another embodiment, the conductive protective layer 400 can completely cover the wiring layer 300.

The conductive protective layer 400 can be a single layer or a multilayer prepared by at least one material selected from the group consisting of nickel, gold, platinum and titanium. In the embodiment, the conductive protective layer is a nickel/gold stack layer. A thickness of the conductive protective layer 400 is in a range of 1-10 nm, 10-100 nm, or 100-2000 nm. The conductive protective layer can be prepared by means of sputtering, evaporation and the like.

In an embodiment, a projected area of the conductive protective layer 400 in a vertical direction is larger than or equal to a projected area of lower surfaces of the conductive solder pads 500 in the vertical direction, so that a whole lower surface of the conductive solder pads 500 is in contact with the wiring layer 300 through the conductive protective layer 400, which can prevent oxidation of the wiring layer 300 connected to the conductive solder pads 500, so as to effectively improve the associativity and the conductivity of the conductive solder pads 500. When the projected area of the conductive protective layer 400 in the vertical direction is smaller than the projected area of the lower surfaces of the conductive solder pads 500 in the vertical direction, a part of the wiring layer 300 which is not covered by the conductive protective layer 400 and needs to be connected with the conductive solder pads 500 will be oxidized, the conductive solder pad 500 is still prone to fall off or poor contact with the wiring layer 300, and the effect of improving the associativity and the conductivity of the conductive solder pads 500 cannot be achieved.

### Embodiment 4

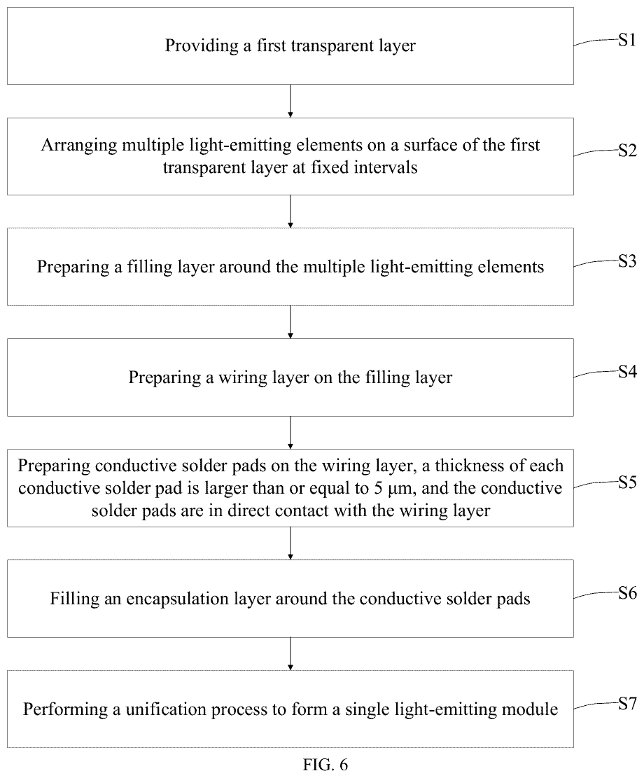

The embodiment provides a preparation method of a light-emitting module. FIG. 6 illustrates a flowchart for describing the preparation method of the light-emitting module according to the embodiment 4 of the disclosure.

The preparation method includes the following steps S1-S7.
In step S1, a first transparent layer 1001 is provided.
In step S2, multiple light-emitting elements 200 are arranged on a surface of the first transparent layer 1001 at fixed intervals.
In step S3, a filling layer 210 is prepared around the light-emitting elements 200.
In step S4, a wiring layer 300 is prepared on the filling layer 210.
In step S5, conductive solder pads 500 are prepared on the wiring layer 300, a thickness of each conductive solder pad 500 is larger than or equal to 5 μm, and the conductive solder pads 500 are in direct contact with the wiring layer 300.
In step S6, an encapsulation layer 600 is filled around the conductive solder pads 500.
In step S7, a unification process is performed to form a single light-emitting module.

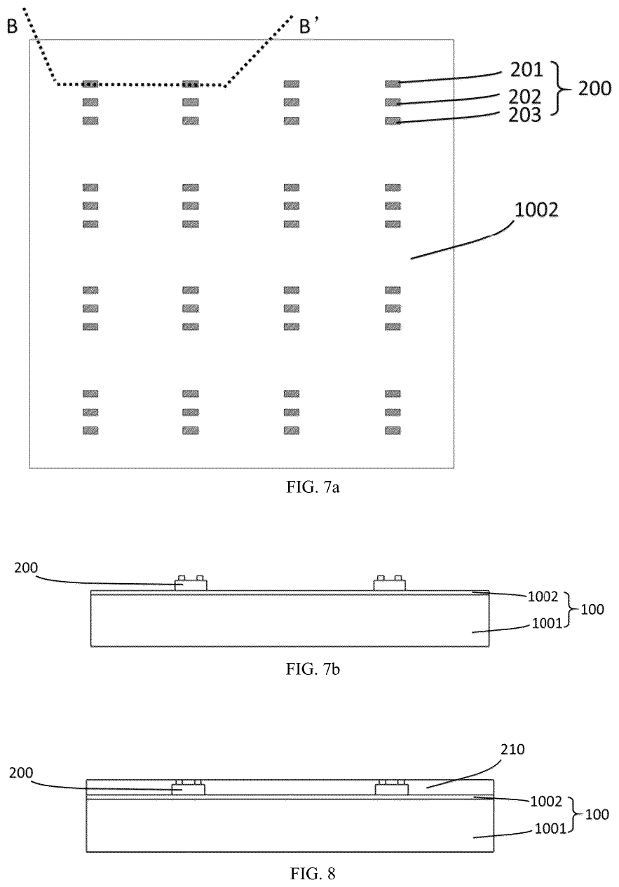

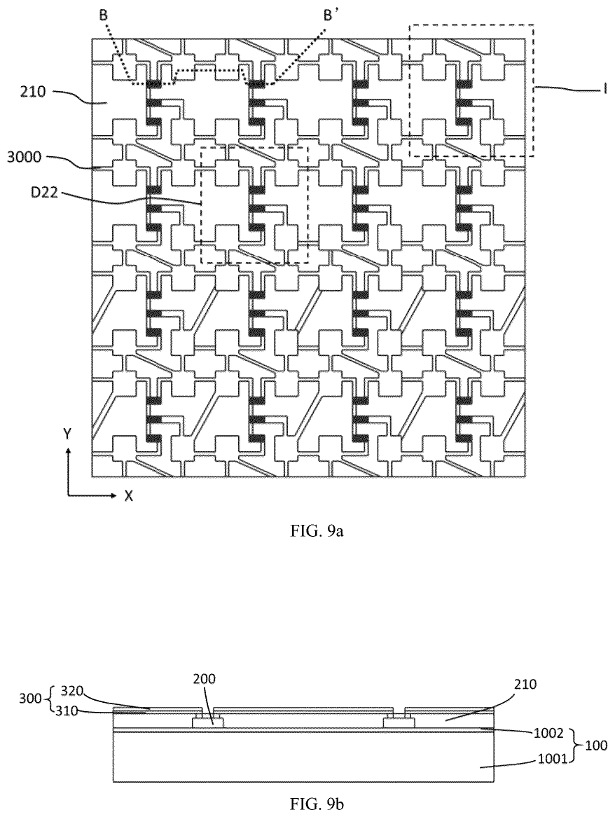

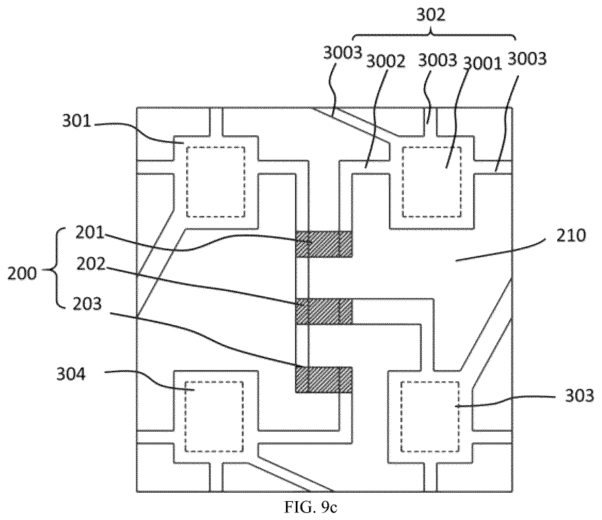

The following is a detail description in conjunction with the drawings.
In step S1, the first transparent layer 1001 is provided, and the first transparent layer 1001 can be provided according to the embodiment 1. The first transparent layer 1001 includes a first surface and a second surface, and the first surface is a light-emitting surface of the light-emitting module.
In step S2, as shown in FIG. 7a and FIG. 7b, FIG. 7 illustrates a section diagram of the light-emitting module taken along a section line B-B′ in FIG. 7b, and a series arrays composed of the light-emitting elements 200 are fixed on the second surface of the first transparent layer 1001. Each array includes a series light-emitting units, each light-emitting unit corresponds to a pixel point, and the light-emitting unit includes at least three light-emitting elements 200 emitting light in different wavelength ranges. In an embodiment, a sapphire substrate is selected as the first transparent layer 1001, and the light-emitting elements 200 are connected to the first transparent layer 1001 through a second transparent layer 1002. The second transparent layer 1002 can be provided according to the embodiment 1. The second transparent layer 1002 is covered on the second surface of the first transparent layer 1001.
In step S3, as shown in FIG. 8, the filling layer 210 is prepared around the light-emitting elements 200, and the filling layer 210 is filled between adjacent light-emitting elements 200 or around side walls of the light-emitting elements 200.
In step S4, as shown in FIG. 9a and FIG. 9b, FIG. 9b illustrates a schematic section diagram of the light-emitting module taken along a section line B-B′ in FIG. 9a, and a total wiring layer 3000 is prepared on the filling layer 210. The total wiring layer 3000 includes multiple unitized wiring layers 300. The unitized wiring layers 300 are arranged in columns in a first direction X and are arranged in rows in a second direction Y, and the first direction is perpendicular to the second direction. FIG. 9c illustrates an enlarged schematic diagram of a part I of FIG. 9b. As shown in FIG. 9c, each unitized wiring layer 300 includes a first sub wiring 301, a second sub wiring 302, a third wiring 303 and a fourth wiring 304. A first light-emitting element 201 is electrically connected to the first sub wiring 301 and the second sub wiring 302, a second light-emitting element 202 is electrically connected to the first sub wiring 301 and the third sub wiring 303, and a third light-emitting element 203 is electrically connected to the first sub wiring 301 and the fourth sub wiring 304. Each sub wiring 301-304 defines a first area 3001, a second area 3002 and a third area 3003. Specifically, the first area 3001 is an area that the wiring layer 300 overlaps with the conductive solder pads 500 in a vertical direction, the second area 3002 is an area connecting the first area 3001 and the light-emitting elements 200, and the third area 3003 is an area extending from the first area 3001 to an edge of the light-emitting module.

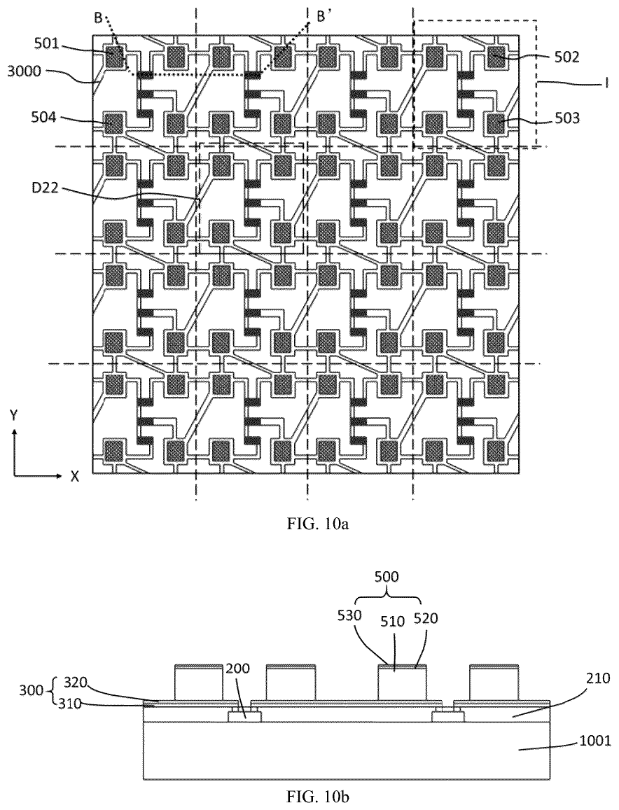

A wiring layer (D22) 300 in a second column and a second a row is taken as an example to describe connection relationships between unitized wiring layers. It should be noted that, for example, a unitized wiring layer in a first row and a first column is abbreviated as D11, a unitized wiring layer in a second row and a third column is abbreviated as D23, a unitized wiring layer in a third row and a fifth column is abbreviated as D35, and the like. A first sub wiring 301_{D22} of D22 is connected to a fourth sub wiring 304D₁₂ of D12, a second sub wiring 302_{D21} of D21 and a third sub wiring 303D₂₁ of D21. A second sub wiring 302_{D22} of D22 is connected to a third sub wiring 303_{D12} of D12, the fourth sub wiring 304D₁₂ of D12 and a first sub wiring 301_{D23} of D23. A third sub wiring 303_{D22} of D22 is connected to a second sub wiring 302D₃₂ of D32, the first sub wiring 301_{D23} of D23 and a fourth sub wiring 304D₂₃ of D23. A fourth sub wiring 304_{D22} of D22 is connected to the third sub wiring 303D₂₁ of D21, a first sub wiring 301_{D32} of D32 and the second sub wiring 302D₃₂ of D32. Other unitized wiring layers 300 are arranged in this way. The unitized wiring layers 300 are connected to each other according to this connection method to make the total wiring layer 3000 in an interconnected state.
In step S5, as shown in FIG. 10a and FIG. 10b, FIG. 10b illustrates a schematic section diagram of the light-emitting module taken along a section line B-B′ in FIG. 10a, and the conductive solder pads 500 are prepared on the wiring layer 300. The conductive solder pads 500 are prepared on the first area 3001 of the wiring layer 300 through the electroplating method, a thickness of each conductive solder pad 500 is larger than or equal to 5 μm, and the conductive solder pads 500 are in direct contact with the wiring layer 300.
In step S6, as shown in FIG. 11, the encapsulation layer 600 is filled around the conductive solder pads 500, and the encapsulation layer 600 can be disposed according to the embodiment 1.
In step S7, the unification process is performed to form the single light-emitting module.

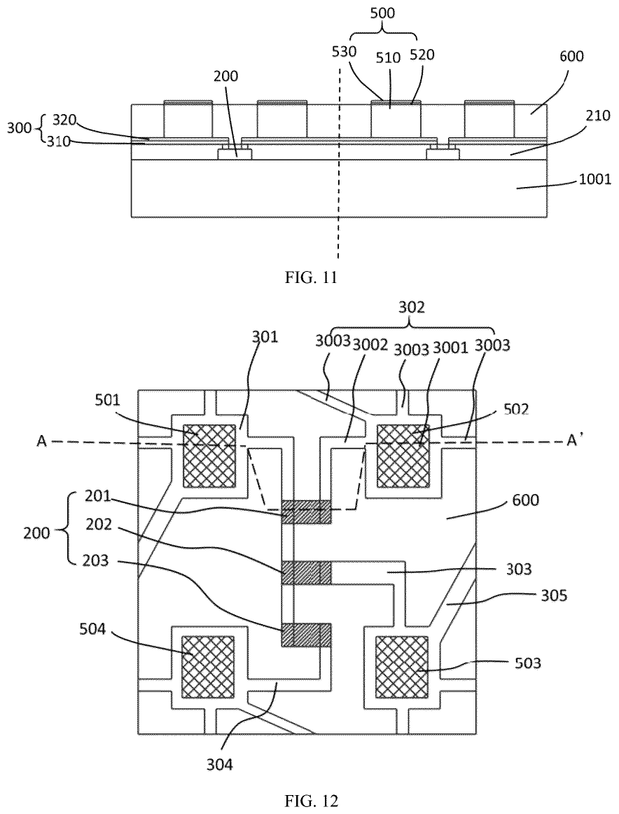

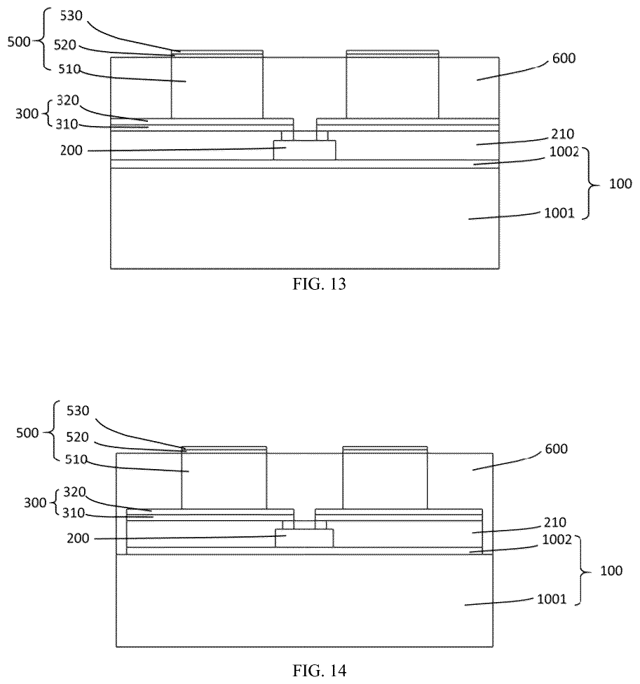

FIG. 12 illustrates a schematic plane diagram of the light-emitting module prepared by using the preparation method, and a corresponding section diagram is shown in FIG. 13. The light-emitting module includes: the first transparent layer 1001, the light-emitting elements 200, the filling layer 210, the wiring layer 300, the conductive solder pads 500 and the encapsulation layer 600. Specifically, the wiring layer 300 includes the first sub wiring 301, the second sub wiring 302, the third sub wiring 303 and the fourth sub wiring 304. The first light-emitting element 201 is electrically connected to the first sub wiring 301 and the second sub wiring 302, the second light-emitting element 202 is electrically connected to the first sub wiring 301 and the third sub wiring 303, and the third light-emitting element 203 is electrically connected to the first sub wiring 301 and the fourth sub wiring 304. Each sub wiring 301-304 defines the first area 3001, the second area 3002 and the third area 3003. Specifically, the first area 3001 is the area that the wiring layer 300 overlaps with the conductive solder pads 500 in the vertical direction, the second area 3002 is the area connecting the first area 3001 and the light-emitting elements 200, and the third area 3003 is the area extending from the first area 3001 to the edge of the light-emitting module. In an embodiment, the third area 3003 includes at least three pins 305 extending from the first area 3001 to the edge of the light-emitting module. However, it is not limited to this, the third area 3003 only needs to have enough area extending to the edge of the light-emitting module to connect with three adjacent light-emitting modules. Sides of the pins 305 of the third area 3003 is flush with a side of the encapsulation layer 600.

The first transparent layer 1001, the light-emitting elements 200, the filling layer 210, the conductive solder pads 500 and the encapsulation layer 600 can be designed according to the embodiment 1.

In the preparation method described in the embodiment, the wiring layer 300 is designed to make each unitized wiring layer 300 form interconnection before performing the unification process, thus the conductive solder pads 500 can be prepared on corresponding positions on each unitized wiring layer through the electroplating method and the like without disposing a seed layer, so as to simplify the manufacture process. In an embodiment, during preparing the conductive solder pads 500 by electroplating, a wet etching method is used to etch a surface of the wiring layer 300 to remove an oxidation layer of the surface of the wiring layer 300, to thereby make the wiring layer 300 in direct contact with the conductive solder pads 500, and avoid poor electrical bonding caused by oxidation of the wiring layer 300.

In an embodiment, as shown in FIG. 14, the encapsulation layer 600 covers a side wall of the wiring layer 300, which can avoid the oxidation of the wiring layer 300 exposing at the edge of the light-emitting module to cause poor electrical properties.

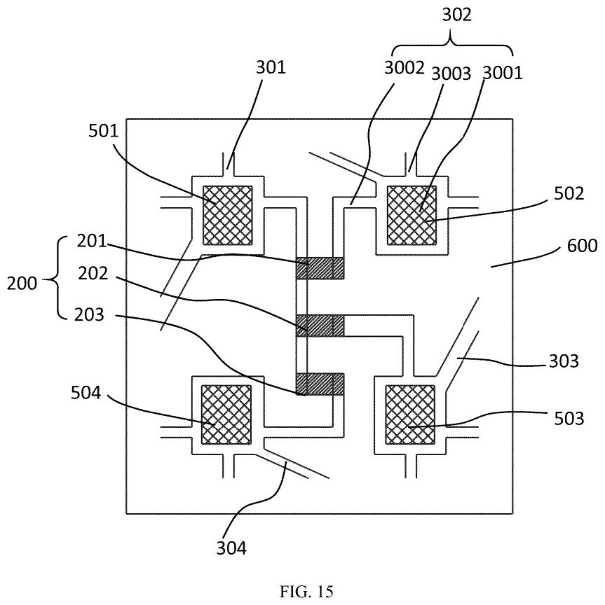

In an embodiment, as shown in FIG. 15, the pins 305 of the wiring layer 300 extending to the edge of the light-emitting module is partially etched, to thereby avoid the poor electrical properties caused by the oxidation of the wiring layer 300 exposing at the edge of the light-emitting module.

### Embodiment 5

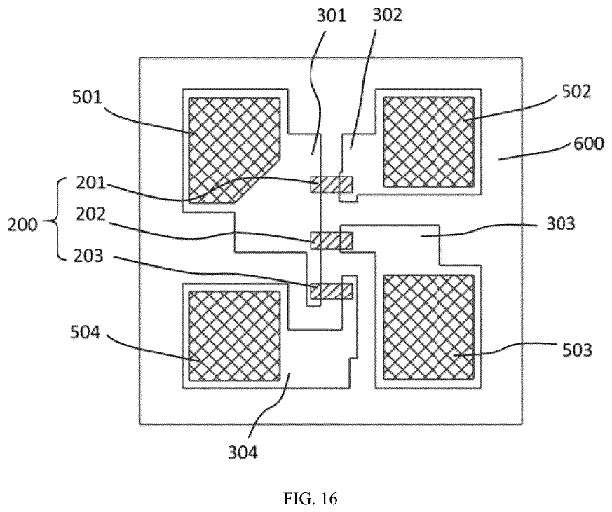

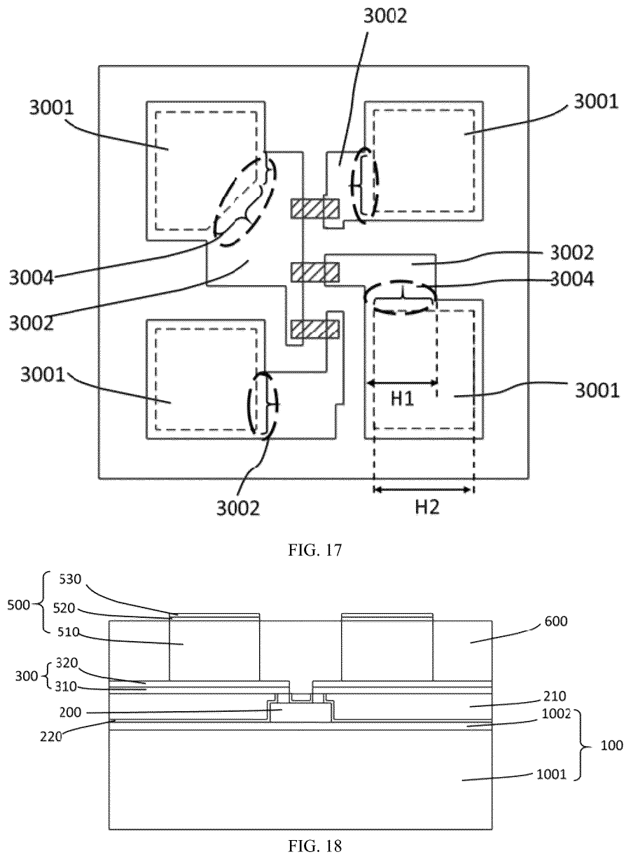

FIG. 16 illustrates a schematic plane diagram of a light-emitting module according to the embodiment 5 of the disclosure, and a corresponding section diagram is shown in FIG. 13. FIG. 17 illustrates a schematic plane diagram of the light-emitting module in FIG. 16 omitting conductive solder pads 500 for easy labeling of a wiring layer 300. The light-emitting module includes: a first transparent layer 1001, light-emitting elements 200, a filling layer 210, the wiring layer 300, the conductive solder pads 500 and an encapsulation layer 600. Specifically, the first transparent layer 1001, the light-emitting elements 200, the filling layer 210, the conductive solder pads 500 and the encapsulation layer 600 are designed according to needs with reference to the aforementioned embodiments.

As shown in FIG. 16 and FIG. 17, the wiring layer 300 defines a first area 3001 and a second area 3002. The first area 3001 is an area that the wiring layer 300 overlaps with the conductive solder pads 500 in a vertical direction, the second area 3002 is an area connecting the first area 3001 and the light-emitting elements 200, and a connection position 3004 is defined between the first area 3001 and the second area 3002. An interface between the encapsulation layer 600 and the conductive solder pads 500 has residual stress due to a large difference in thermal expansion coefficient of the encapsulation layer 600 and the conductive solder pads 500. If a length H1 of the connection position 3004 between the first area and the second area is undersize, the connection position 3004 between the first area and the second area is easy to cause break of the wiring layer 300 at the second area 3002 due to the residual stress, so that the first area 3001 and the second area 3002 are easily disconnected, and resulting in a failure of an electrical connection between the conductive solder pads 500 and the light-emitting elements 200. In the embodiment, the length H1 of the connection position 3004 between the first area and the second area is larger than or equal to 20 μm, thus ensuring a complete part of the second area 3002 to be electrically connected to the light-emitting elements 200 even though the wiring layer 300 at the second area 3002 is cracked.

In an embodiment, the length H1 of the connection position 3004 between the first area and the second area is over 40% of a length of each side of each conductive solder pad 500, thus ensuring a complete part of the second area 3002 to be electrically connected to the light-emitting elements 200 even though the wiring layer 300 at the second area 3002 is cracked. Specifically, a distance between the first area 3001 and an edge of the wiring layer 300 proximate to the light-emitting module is smaller than or equal to 20 μm.

In order to facilitate the client use, a shape of the first solder pad 501 is different from shapes of the second solder pad 502, the third solder pad 503 and the fourth solder pad 504, thus playing a role of identification. It should be noted that a ratio between H1 and H2 can be a ratio between the length H1 of the connection position 3004 between the first area 3001 and the second area 3002 in the first solder pad 501 and a total length of two corresponding sides of the first solder pad 501.

### Embodiment 6

FIG. 18 illustrates a schematic diagram for describing a light-emitting module according to the embodiment 6 of the disclosure.

It is different from the embodiment 1 to the embodiment 5 in that: the light-emitting module further includes an insulating adhesion layer 220, and the adhesion layer 220 is disposed between the light-emitting elements 200 and the filling layer 210. Due to a poor associativity between the filling layer 210 and the light-emitting elements 200, a separation situation may appear between the light-emitting elements 200 and the filling layer 210 during the client use, thus causing brightness attenuation of the light-emitting module. Therefore, the adhesion layer 220 is disposed between the light-emitting elements 200 and the filling layer 210, and a thickness of the adhesion layer 220 is smaller than or equal to 1 μm, specifically, the thickness of the adhesion layer 220 is in a range of 5-100 nm, 100-300 nm or 300-600 nm. The thickness of the above adhesion layer 220 is small, thus having no effect on the structure of the light-emitting module, and the adhesion layer 220 can improve a bonding force between the light-emitting elements 200 and the filling layer 210, and avoid the separation situation appearing between the light-emitting elements 200 and the filling layer 210.

In an embodiment, as shown in FIG. 18, the adhesion layer 220 is a continuous layer, the adhesion layer 220 covers an upper surface and a side wall of each light-emitting element 200 and gaps between adjacent light-emitting elements 200, and exposes a first electrode and a second electrode in each light-emitting element 200.

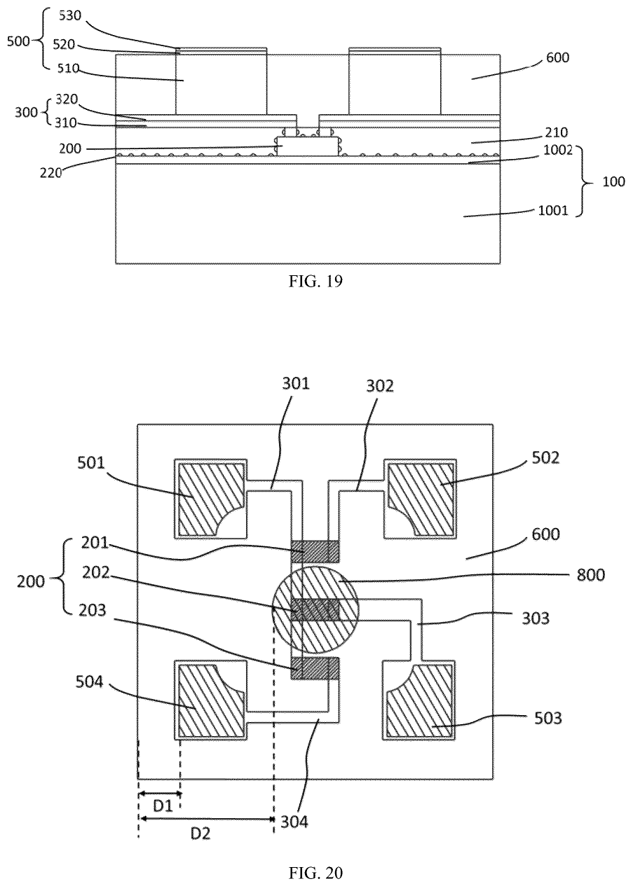

In an embodiment, as shown in FIG. 19, the adhesion layer 220 is a discontinuous layer, the adhesion layer 220 covers parts of the upper surface and the side wall of the light-emitting element 200 and parts of the gaps between the adjacent light-emitting elements 200, and exposes the first electrode and the second electrode in the light-emitting element 200.

It should be noted that the adhesion layer 220 can be remained on the first electrode and the second electrode in the light-emitting element 200, and the remained adhesion layer 220 cannot affect conductivity of the light-emitting module.

### Embodiment 7

FIG. 20 illustrates a schematic plane diagram for describing a light-emitting module according to the embodiment 7 of the disclosure.

It is different from the embodiment 1 to the embodiment 6 in that the light-emitting module further includes a protective solder pad 800, and the protective solder pad 800 is disposed on a side of the encapsulation layer 600 facing away from the light-emitting elements 200.

The protective solder pad 800 is located at a thimble operation area of the light-emitting module. The above thimble operation area is an area covered by a range error of a thimble operating on a surface of the encapsulation layer 600 facing away from the light-emitting elements 200. For example, the thimble operation area is a circular area with a radius not larger than 300 μm. Specifically, the thimble operation area is a circular area with a radius not larger than 150 μm. The thimble has a risk of puncturing the thimble operation area when the light-emitting module is mounted or die-bonded onto the display device, so as to damage the light-emitting elements 200 below the encapsulation layer 600, and resulting in failure of the light-emitting module.

The protective solder pad 800 is added in the thimble operation area of the light-emitting module, when the thimble acts on the above area, it can effectively avoid the thimble puncturing or bursting the encapsulation layer 600, and make the encapsulation layer 600 still have a good protection effect on the light-emitting elements 200, so as to avoid damaging the light-emitting elements 200, and avoid the failure of the light-emitting module.

In an embodiment, the protective solder pad 800 is not electrically connected to the wiring layer 300. The protective solder pad 800 and the conductive solder pads 500 are formed together in a same process, and a material of the protective solder pad 800 is the same as a material of each conductive solder pad 500. The protective solder pad 800 has a good structural strength, various thimbles can be selected to act on the protective solder pad 800 during a subsequent mounting or die-bonding process, so as to improve a speed of the mounting or die-bonding process.

In an embodiment, as shown in FIG. 20, the conductive solder pads 500 are disposed around a periphery of the protective solder pad 800, sides of the conductive solder pads 500 facing towards the protective solder pad 800 are configured in arc shapes, and openings of the arc shapes face towards the protective solder pad 800. The conductive solder pads 500 are disposed as the above structure, a distance between each conductive solder pad 500 and the protective solder pad 800 is increased, thus avoiding a short circuit phenomenon caused by a contact between the conductive solder pads 500 and the protective solder pad 800. In the embodiment, sides of the first solder pad 501, the second solder pad 502, the third solder pad 503 and the fourth solder pad 504 facing towards the protective solder pad 800 are configured in the arc shapes, and the openings of the arc shapes face towards the protective solder pad 800.

In an embodiment, shapes or sizes of the first solder pad 501, the second solder pad 502, the third solder pad 503 and the fourth solder pad 504 are different, which is convenient for identifying a type of the conductive solder pad 500, so as to facilitate a subsequent determination of a cutting position. A total area of the conductive solder pads 500 is 20% to 70% of area of the light-emitting module.

In an embodiment, as shown in FIG. 20, a distance D1 between each conductive solder pad 500 and the edge of the light-emitting module is larger than 20 μm. A distance D2 between the protective solder pad 800 and the edge of the light-emitting module is larger than 20 μm.

In an embodiment, the protective solder pad 800 is disposed at intervals with the first solder pad 501, the second solder pad 502, the third solder pad 503 and the fourth solder pad 504.

In an embodiment, the light-emitting elements 200 includes a first light-emitting element 201, a second light-emitting element 202 and the third light-emitting element 203. The protective solder pad 800 covers at least a part of the second light-emitting element 202 below it, or the protective solder pad 800 covers at least the multiple light-emitting elements 202 below it.

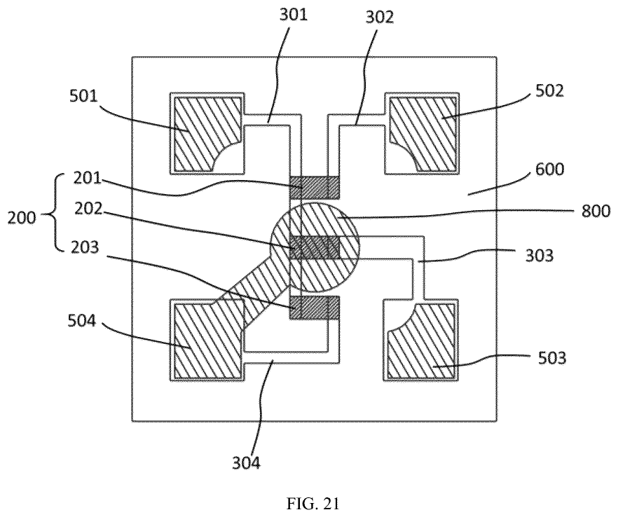

In an embodiment, as shown in FIG. 21, the protective solder pad 800 can be a part of the first solder pad 501, the second solder pad 502, the third solder pad 503 or the fourth solder pad 504. A part of the corresponding solder pad extending to a central area of the light-emitting module is formed as the protective solder pad 800 to protect the thimble operation area of the light-emitting module, so as to effectively avoid the thimble puncturing or bursting the encapsulation layer 600.

According to the above technical scheme, the filling layer 210 is disposed between the adjacent light-emitting elements 200 in the disclosure, the filling layer 210 is prepared by solidifying a material with good fluidity, and the particle size of the black filling component in the filling layer 210 is not larger than 1/10 of the thickness of the light-emitting element 200, thus improving a covering effect of the filling layer 210 on the light-emitting elements 200, and improving the contrast of the light-emitting module. The encapsulation layer 600 is prepared around the conductive solder pads 500, and the encapsulation layer 600 has a large thickness and strength, thus protecting the light-emitting elements 200 and the wiring layer 300 from damage from external factors. Therefore, different insulation structures can be disposed on different positions of the light-emitting module to simultaneously meet requirements of the different positions of the light-emitting module, thus making the light-emitting module have a high contract and mechanical property.

In an embodiment, the conductive solder pad 500 includes a protective layer 530. Before installing the light-emitting module on the display device, the above protective layer 530 completely covers an upper surface of the conductive layer 510, which can effectively prevent oxidation of the conductive layer 510, and improve the stability of the light-emitting module. When installing the light-emitting module on the display device, the above protective layer 530 is damaged or removed, and the protective layer 530 has no effects on the associativity and the conductivity of the conductive solder pads 500.

In an embodiment, the conductive solder pad 500 further includes a eutectic layer 540, the eutectic layer 540 can effectively enhance the associativity of the light-emitting module during applying, and it is not necessary to print solder paste again during applying, thus improving the convenience of the client use.

In an embodiment, the conductive protective layer 400 is added between the wiring layer 300 and the conductive solder pads 500, which can effectively prevent oxidation of a part of the wiring layer 300 used for connecting to the conductive solder pads 500, and improve a phenomenon of the conductive solder pads 500 being prone to fall off or poor contact caused by the oxidation of the wiring layer 300, so as to improve the associativity and the conductivity of the conductive solder pads 500.

In an embodiment, the protective solder pad 800 is added in the thimble operation area of the light-emitting module, when the thimble acts on the above area, it can effectively avoid the thimble puncturing or bursting the encapsulation layer 600, and make the encapsulation layer 600 still have a good protection effect on the light-emitting elements 200, so as to avoid damaging the light-emitting elements 200, and avoid the failure of the light-emitting module. The protective solder pad 800 and the conductive solder pads 500 are formed together in a same process, and a material of the protective solder pad 800 is the same as a material of each conductive solder pad 500. The protective solder pad 800 has a good structural strength, various thimbles can be selected to act on the protective solder pad 800 during a subsequent mounting or die-bonding process, so as to improve a speed of the mounting or die-bonding process.

The above descriptions are merely embodiments of the disclosure, it should be pointed out that multiple improvements and substitutions can be made by those skilled in the art without departing from a technical principle of the disclosure, and the multiple improvements and substitutions should be regarded as a scope of protection of the disclosure.

What is claimed is:

1. A light-emitting module, comprising:
a plurality of light-emitting elements arranged at intervals; wherein a thickness of each of the plurality of light-emitting elements is smaller than or equal to 15 microns (μm);
a filling layer, filled between adjacent two of the plurality of light-emitting elements;
a wiring layer, disposed on the plurality of light-emitting elements, and configured to electrically connect to the plurality of light-emitting elements; and
conductive solder pads, disposed on a side of the wiring layer facing away from the plurality of light-emitting elements, and electrically connected to the wiring layer; and
wherein the filling layer contains a black filling component, and a particle size of the black filling component is smaller than or equal to 1/10 of the thickness of each of the plurality of light-emitting elements.

2. The light-emitting module as claimed in claim 1, wherein the black filling component of the filling layer comprises at least one selected from the group consisting of carbon black, titanium nitride, iron oxide, ferrosoferric oxide and iron powder, and the particle size of the black filling component is smaller than or equal to 1 μm.

3. The light-emitting module as claimed in claim 1, wherein the filling layer covers over 50% of a thickness of a side wall of each of the plurality of light-emitting elements proximate to a light-emitting surface of the light-emitting element, and a distance between adjacent two of the plurality of light-emitting elements is smaller than 50 μm.

4. The light-emitting module as claimed in claim 1, wherein the light-emitting module further comprises: a transparent layer; the transparent layer is provided with the plurality of light-emitting elements thereon, and the transparent layer comprises: a first transparent layer and a second transparent layer; and the second transparent layer is disposed between the first transparent layer and the plurality of light-emitting elements, a thickness of the first transparent layer is larger than 10 μm, and a thickness of the second transparent layer is in a range of 1-10 μm.

5. The light-emitting module as claimed in claim 1, wherein the wiring layer comprises: a first layer and a second layer, the first layer is in direct contact with the plurality of light-emitting elements, and the second layer is disposed on the first layer; and a material of the first layer comprises at least one selected from the group consisting of titanium, nickel, titanium nitride, tantalum nitride and tantalum, a material of the second layer comprises at least one selected from the group consisting of copper, aluminum, and gold, and a thickness of the wiring layer is in a range of 50-1000 nanometers (nm).

6. The light-emitting module as claimed in claim 1, wherein the light-emitting module further comprises: a seed layer, and the seed layer is disposed between the wiring layer and the conductive solder pads; and a thickness of the seed layer is in a range of 100-2000 nm.

7. The light-emitting module as claimed in claim 1, wherein the light-emitting module further comprises: an insulation layer, and the insulation layer is filled around the wiring layer.

8. The light-emitting module as claimed in claim 1, wherein each of the conductive solder pads comprises: a conductive layer, a bonding layer and a protective layer; and a thickness of the conductive layer is in a range of 10-50 μm, a thickness of the bonding layer is in a range of 3-5 μm, and a thickness of the protective layer is in a range of 25-50 nm.

9. The light-emitting module as claimed in claim 1, wherein each of the conductive solder pads comprises: a conductive layer, a bonding layer and a eutectic layer; and a thickness of the conductive layer is in a range of 10-50 μm, a thickness of the bonding layer is in a range of 3-5 μm, and a thickness of the eutectic layer is in a range of 10-50 nm.

10. The light-emitting module as claimed in claim 1, wherein each of the conductive solder pads comprises: a conductive layer, a bonding layer, a eutectic layer and a protective layer; and a thickness of the conductive layer is in a range of 10-50 μm, a thickness of the bonding layer is in a range of 3-5 μm, a thickness of the eutectic layer is in a range of 10-50 nm, and a thickness of the protective layer is in a range of 25-50 nm.

11. The light-emitting module as claimed in claim 8, wherein the light-emitting module further comprises: an encapsulation layer, and the encapsulation layer is filled around the conductive solder pads; a thickness of the encapsulation layer is larger than 20 μm, and a surface of the encapsulation layer facing away from the wiring layer is flush with a surface of the conductive layer facing away from the wiring layer; and the encapsulation layer contains doped particles, and a particle size of each of the doped particles is larger than 1 μm.

12. The light-emitting module as claimed in claim 1, wherein a total area of the conductive solder pads is 20% to 70% of an area of the light-emitting module.

13. The light-emitting module as claimed in claim 12, wherein a thickness of each of the conductive solder pads is larger than 5 μm, and the wiring layer is in direct contact with the conductive solder pads.

14. The light-emitting module as claimed in claim 1, wherein the light-emitting module further comprises: an adhesion layer, and the adhesion layer is disposed between the plurality of light-emitting elements and the filling layer.

15. The light-emitting module as claimed in claim 11, wherein the light-emitting module further comprises: a protective solder pad, the protective solder pad is disposed on a side of the encapsulation layer facing away from the plurality of light-emitting elements, and is located on a thimble operation area of the light-emitting module.

16. The light-emitting module as claimed in claim 12, wherein the light-emitting module further comprises: a conductive protective layer, and the conductive protective layer is disposed between the conductive solder pads and the wiring layer.

17. The light-emitting module as claimed in claim 1, wherein the wiring layer defines a first area and a second area; the first area is an area that the wiring layer overlaps with the conductive solder pads in a vertical direction, the second area is an area connecting the first area and the plurality of light-emitting elements; and a connection position is defined between the first area and the second area, and a length of the connection position between the first area and the second area is larger than 20 μm.

18. The light-emitting module as claimed in claim 1, wherein the wiring layer defines a first area and a second area; the first area is an area that the wiring layer overlaps with the conductive solder pads in a vertical direction, the second area is an area connecting the first area and the plurality of light-emitting elements; and a connection position is defined between the first area and the second area, and a length of the connection position between the first area and the second area is over 40% of a length of each side of each of the conductive solder pads.

19. A light-emitting module, comprising:
a plurality of light-emitting elements arranged at intervals;
a filling layer, filled between adjacent two of the plurality of light-emitting elements;
a wiring layer, disposed on the plurality of light-emitting elements, and configured to electrically connect to the plurality of light-emitting elements; and
conductive solder pads, disposed on a side of the wiring layer facing away from the plurality of light-emitting elements, and electrically connected to the wiring layer; and
wherein the filling layer contains a black filling component, and a particle size of the black filling component is smaller than or equal to 1 μm.

20. A display device, comprising a plurality of light-emitting modules as claimed in claim 1.
